(19) United States
(12) Patent Application Publication
(10) Pub. No.: US 2023/0286079 A1
(43) Pub. Date: Sep. 14, 2023

(54) LASER PROCESSING MACHINE AND PROCESSING METHOD OF WORKPIECE

(71) Applicant: DISCO CORPORATION, Tokyo (JP)

(72) Inventors: Satoshi KUMAZAWA, Tokyo (JP); Masatoshi NAYUKI, Tokyo (JP); Keisuki NISHIMOTO, Tokyo (JP)

(21) Appl. No.: 18/181,716

(22) Filed: Mar. 10, 2023

(30) Foreign Application Priority Data
Mar. 11, 2022 (JP) 2022-037782

(51) Int. Cl. B23K 26/046; B23K 26/06

(52) U.S. Cl. CPC B23K 26/046; B23K 26/0665; B23K 26/0626

(57) ABSTRACT

There is provided a laser processing machine for processing a workpiece having a scribe line set thereon. The processing machine includes a controller configured to perform a procedure of moving a focal point of a laser beam in a first moving direction, which intersects a processing feed direction, in a range of a width of the line when the focal point and the holding unit relatively move along the processing feed direction, and a procedure of controlling power of the laser beam so that, upon movement of the focal point in the first moving direction, the power of the laser beam is smaller when the focal point is located in regions on outer edge sides of the line than when the focal point is located in a region on a center side of the scribe, whereby a groove is formed along the line.

### BACKGROUND OF THE INVENTION

### Field of the Invention

The present invention relates to a laser processing machine for use when processing a plate-shaped workpiece such as a wafer, a program for use in controlling the laser processing machine, a non-transitory recording medium with the program recorded thereon, and a processing method of the workpiece.

### Description of the Related Art

For electronic equipment represented by mobile phones and personal computers, device chips each of which has a device of an electronic circuit or the like have become essential elements. Device chips are obtained, for example, by defining a wafer, which is made of a semiconductor such as silicon, into a plurality of regions with streets (scribe lines) on the side of a front surface thereof, and after formation of devices in the respective regions, dividing the wafer along the streets.

When dividing a plate-shaped workpiece like a wafer into small pieces such as device chips, a cutting machine with an annular cutting stone tool called a “cutting blade” and fitted on a spindle as a rotating shaft is used, for example. By causing the cutting blade to cut at a high rotational speed into the workpiece along streets, the workpiece is cut off along the streets, and is divided into a plurality of small pieces.

To reduce interconnection capacitance as a cause of delay of signals, low dielectric constant materials (low-k materials) that are low in dielectric constant compared with conventional materials have been adopted in recent years as interlayer dielectric films or the like that constitute devices. However, these low dielectric constant materials are brittle compared with such conventional materials, and may be broken and delaminated when processed by a mechanical method like the method mentioned above. When a workpiece having a film of low dielectric constant material is mechanically processed, the film is therefore removed beforehand by a laser beam at its portions which overlap streets.

Specifically, the film is removed at its portions, which overlap the streets, by a processing method called “laser ablation” that causes absorption of the laser beam into the workpiece. With this processing method, however, the workpiece is fused and evaporated at parts thereof by the laser beam, so that contaminants such as debris and recast layers tend to occur. For example, if the contaminants stick edges and walls of grooves formed along the streets upon the removal of the film, the resulting device chips have lower quality.

To solve this problem, methods have been proposed. According to these methods, a weak laser beam is additionally applied to edges and the like of grooves where contaminants are stuck, thereby removing the contaminants (see, for example, JP 2009-49390A and JP 2010-284670A). By applying the weak laser beam to regions, at which the contaminants are stuck, of the workpiece, the contaminants are fused and evaporated by the weak laser beam, and hence are removed from the workpiece. Because of the use of such a weak laser beam in these methods, the grooves are not significantly changed in profile.

### SUMMARY OF THE INVENTION

However, with a method that as mentioned above, a weak laser beam is additionally applied after the formation of a groove by irradiation of a laser beam to a workpiece, contaminants are no longer appropriately removed if the position of the weak laser beam applied to the workpiece deviates even slightly. It may be contemplated to split a laser beam using a diffraction grating and hence to perform the formation of a groove and the removal of contaminants at the same time. With this method, however, the position of the laser beam to be applied to a workpiece can be hardly changed if a need arises for the formation of a groove of a different width or for a like purpose, because the diffraction grating so used is fixed in the mode of splitting and is costly.

The present invention therefore has, as objects thereof, the provision of a laser processing machine, a program, a non-transitory storage medium, and a processing method which can remove contaminants that stick in the groove while forming a groove in a workpiece and can flexibly change the position of a laser beam to be applied to the workpiece.

In accordance with a first aspect of the present invention, there is provided a laser processing machine for processing a workpiece by applying a laser beam along scribe lines having a predetermined width and set on the workpiece, including a holding unit that holds the workpiece, a laser beam irradiation unit that applies the laser beam so that the laser beam is focused on the workpiece held on the holding unit, a processing feed mechanism that relatively moves a focal point, at which the laser beam is focused, and the holding unit along a processing feed direction, and a controller that has a processing device and a storage device and is configured to control the laser beam irradiation unit and the processing feed mechanism according to a program stored in the storage device. The laser beam irradiation unit has a laser oscillator that generates the laser beam, a condenser that focuses the laser beam, which has been generated by the laser oscillator, on the focal point, and a first focal-point moving unit that is arranged between the laser oscillator and the condenser and moves the focal point in a first moving direction, which intersects the processing feed direction, on the workpiece, and the controller performs, to form a groove along the scribe line, according to the program, a procedure of relatively moving the focal point and the holding unit along the processing feed direction with a direction of the width of the scribe line set perpendicular to the processing feed direction, a procedure of moving the focal point in the first moving direction in a range of the width of the scribe line when the focal point and the holding unit relatively move along the processing feed direction, and a procedure of controlling power of the laser beam so that, upon movement of the focal point in the first moving direction, the power of the laser beam is smaller when the focal point is located in regions on outer edge sides of the scribe line than when the focal point is located in a region on a center side of the scribe line.

Preferably, the laser beam irradiation unit may further have a second focal-point moving unit that is arranged between the laser oscillator and the condenser and move the focal point in a second moving direction, which intersects the first moving direction, on the workpiece, and the controller may further perform, according to the program, a procedure of moving the focal point in the second moving direction when the focal point and the holding unit relatively move along the processing feed direction.

Also preferably, upon movement of the focal point in the second moving direction, the controller may further perform, according to the program, a procedure of controlling a range of the movement of the focal point in the first moving direction so that the range of the movement of the focal point in the first moving direction is wider on a backward side than on a forward side in the direction in which the focal point and the holding unit relatively move.

In accordance with a second aspect of the present invention, there is provided a program for use when forming a groove along a scribe line, which has a predetermined width and is set on a workpiece, by a laser processing machine having a holding unit that holds the workpiece, a laser beam irradiation unit that applies a laser beam so that the laser beam is focused on the workpiece held on the holding unit, a processing feed mechanism that relatively moves a focal point, at which the laser beam is focused, and the holding unit along a processing feed direction, and a controller that has a processing device and a storage device and is configured to control the laser beam irradiation unit and the processing feed mechanism according to the program, the laser beam irradiation unit having a laser oscillator that generates the laser beam, a condenser that focuses the laser beam, which has been generated by the laser oscillator, on the focal point, and a first focal-point moving unit that is arranged between the laser oscillator and the condenser and moves the focal point in a first moving direction, which intersects the processing feed direction, on the workpiece, the program causing the controller to perform a procedure of relatively moving the focal point and the holding unit along the processing feed direction with a direction of the width of the scribe line set perpendicular to the processing feed direction, a procedure of moving the focal point in the first moving direction in a range of the width of the scribe line when the focal point and the holding unit relatively move along the processing feed direction, and a procedure of controlling power of the laser beam so that, upon movement of the focal point in the first moving direction, the power of the laser beam is smaller when the focal point is located in regions on outer edge sides of the scribe line than when the focal point is located in a region on a center side of the scribe line.

Preferably, the laser beam irradiation unit may further have a second focal-point moving unit that is arranged between the laser oscillator and the condenser and moves the focal point in a second moving direction, which intersects the first moving direction, on the workpiece, and the program may cause the controller to further perform a procedure of moving the focal point in the second moving direction when the focal point and the holding unit relatively move along the processing feed direction.

Also preferably, the program may cause, upon movement of the focal point in the second moving direction, the controller to further perform a procedure of controlling a range of the movement of the focal point in the first moving direction so that the range of the movement of the focal point in the first moving direction is wider on a backward side than on a forward side in the direction in which the focal point and the holding unit relatively move.

In accordance with a third aspect of the present invention, there is provided a non-transitory recording medium recording a program for use when forming a groove along a scribe line, which has a predetermined width and is set on a workpiece, by a laser processing machine having a holding unit that holds the workpiece, a laser beam irradiation unit that applies a laser beam so that the laser beam is focused on the workpiece held on the holding unit, a processing feed mechanism that relatively moves a focal point, at which the laser beam is focused, and the holding unit along a processing feed direction, and a controller that has a processing device and a storage device and is configured to control the laser beam irradiation unit and the processing feed mechanism according to the program, the laser beam irradiation unit having a laser oscillator that generates the laser beam, a condenser that focuses the laser beam, which has been generated by the laser oscillator, on the focal point, and a first focal-point moving unit that is arranged between the laser oscillator and the condenser and moves the focal point in a first moving direction, which intersects the processing feed direction, on the workpiece, the program causing the controller to perform a procedure of relatively moving the focal point and the holding unit along the processing feed direction with a direction of the width of the scribe line set perpendicular to the processing feed direction, a procedure of moving the focal point in the first moving direction in a range of the width of the scribe line when the focal point and the holding unit relatively move along the processing feed direction, and a procedure of controlling power of the laser beam so that, upon movement of the focal point in the first moving direction, the power of the laser beam is smaller when the focal point is located in regions on outer edge sides of the scribe line than when the focal point is located in a region on a center side of the scribe line.

In accordance with a forth aspect of the present invention, there is provided a processing method of a workpiece, the processing method being for use when forming a groove along a scribe line, which has a predetermined width and is set on the workpiece, by a laser processing machine having a holding unit that holds the workpiece, a laser beam irradiation unit that applies a laser beam so that the laser beam is focused on the workpiece held on the holding unit, and a processing feed mechanism that relatively moves a focal point, at which the laser beam is focused, and the holding unit along a processing feed direction, the processing method including a step of relatively moving the focal point and the holding unit along the processing feed direction with a direction of the width of the scribe line set perpendicular to the processing feed direction, a step of moving the focal point in a first moving direction, which intersects the processing feed direction, in a range of the width of the scribe line when the focal point and the holding unit relatively move along the processing feed direction, and a step of controlling power of the laser beam so that, upon movement of the focal point in the first moving direction, the power of the laser beam is smaller when the focal point is located in regions on outer edge sides of the scribe line than when the focal point is located in a region on a center side of the scribe line.

Preferably, the processing method may further include a step of moving the focal point in a second moving direction, which intersects the first moving direction, when the focal point and the holding unit relatively move along the processing feed direction.

Also preferably, the processing method may further include a step of, upon movement of the focal point in the second moving direction, controlling a range of the movement of the focal point in the first moving direction so that the range of the movement of the focal point in the first moving direction is wider on a backward side than on a forward side in the direction in which the focal point and the holding unit relatively move.

According to the laser processing machine, the program, the non-transitory storage medium, and the processing method of the first to fourth aspects of the present invention, when the focal point of the laser beam and the holding unit relatively move along the processing feed direction, the focal point moves in the first moving direction, which intersects the processing feed direction, in the range of the width of the scribe line, and the power of the laser beam is controlled such that the power of the laser beam is smaller when the focal point is located in the regions on the outer edge sides of the scribe line than when the focal point is located in the region on the center side of the scribe line. Therefore, the groove is formed in the workpiece with the laser beam of high power applied to the region on the center side of the scribe line, and in parallel with the formation of this groove, contaminants stuck in the groove are removed with the laser beam of low power applied to the regions on the outer edge sides of the scribe line.

Further, according to the laser processing machine, the program, the non-transitory storage medium, and the processing method of the first to fourth aspects of the present invention, the formation of the groove and the removal of the contaminants are performed in parallel by moving the focal point with the first focal-point moving unit in the first moving direction, which intersects the processing feed direction, without splitting of the laser beam through a diffraction grating or the like. Compared with a case in which the laser beam is split through the diffraction grating, the position of the laser beam to be applied to the workpiece can therefore be flexibly changed because the position of the laser beam to be applied to the workpiece is moved in the first moving direction by the first focal-point moving unit.

According to the first to fourth aspects of the present invention, there are provided, as described above, a laser processing machine, a program, a non-transitory storage medium, and a processing method which can remove contaminants that stick in the groove while forming a groove in a workpiece and can flexibly change the position of a laser beam to be applied to the workpiece.

The above and other objects, features and advantages of the present invention and the manner of realizing them will become more apparent, and the invention itself will best be understood from a study of the following description and appended claims with reference to the attached drawings showing a preferred embodiment of the above-mentioned aspects of the invention.

### BRIEF DESCRIPTION OF THE DRAWINGS

FIG. 1 is a perspective view illustrating a laser processing machine according to an embodiment;

FIG. 2 is a diagram illustrating the construction of a laser beam irradiation unit according to the embodiment;

FIG. 3 is a function block diagram schematically illustrating the functional configuration of a controller realized by a program according to the embodiment;

FIG. 4 is a fragmentary top view of a front surface of a workpiece, which illustrates how a focal point is moved in the range of a width of a street according to the embodiment;

FIG. 5 is a flow chart illustrating a processing method for the workpiece according to the embodiment;

FIG. 6 is a diagram illustrating the construction of a laser beam irradiation unit according to a modification; and

FIG. 7 is a fragmentary top view of a front surface of a workpiece, which illustrates how a focal point is moved in the range of a width of a street according to the modification.

### DETAILED DESCRIPTION OF THE PREFERRED EMBODIMENT

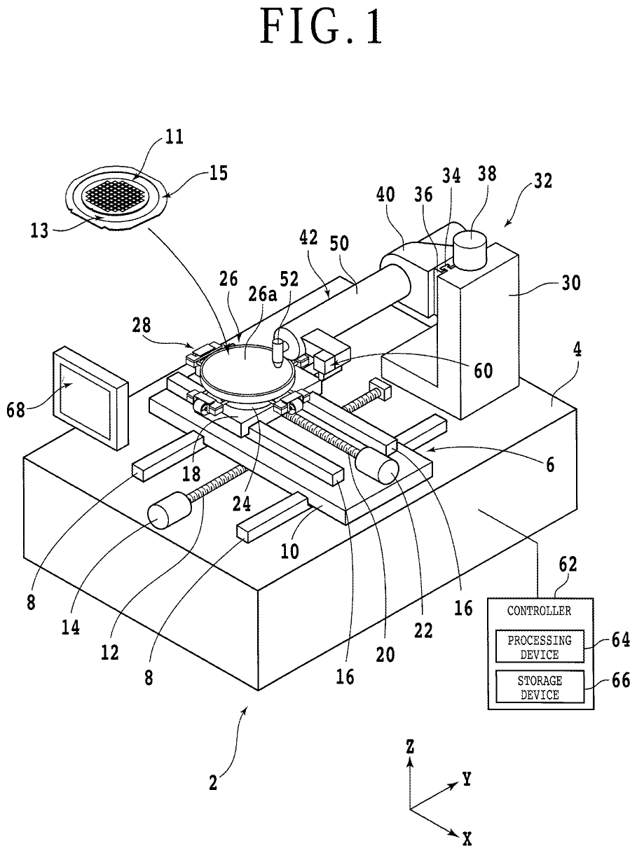

With reference to the attached drawings, a description will hereinafter be made about an embodiment of the present invention. FIG. 1 is a perspective view illustrating a laser processing machine 2 according to the embodiment. It is to be noted that some elements of the laser processing machine 2 are presented as function blocks in FIG. 1. It is also to be noted that an X-axis direction (processing feed direction), a Y-axis direction (indexing feed direction) and a Z-axis direction (vertical direction) which will be used in the following description, are perpendicular to each other.

As illustrated in FIG. 1, the laser processing machine 2 includes a base 4 with individual elements mounted thereon. On an upper surface of the base 4, a horizontal moving mechanism (processing feed mechanism, indexing feed mechanism) 6 is arranged. The horizontal moving mechanism 6 includes a pair of Y-axis guide rails 8, which is fixed on the upper surface of the base 4 and is substantially parallel to the Y-axis direction. To the Y-axis guide rails 8, a Y-axis moving plate 10 is attached in a way that it is slidable along the Y-axis direction.

On a side of a lower surface of the Y-axis moving plate 10, a nut portion (not illustrated) that constitutes a ball screw is disposed. To this nut portion, a screw shaft 12, which is substantially parallel to the Y-axis guide rails 8, is connected in a way that it is rotatable. To one end portion of the screw shaft 12, a Y-axis pulse motor 14 is connected. By rotating the screw shaft 12 with the Y-axis pulse motor 14, the Y-axis moving plate 10 is moved along the Y-axis guide rails 8 (Y-axis direction).

Disposed on an upper surface of the Y-axis moving plate 10 is a pair of X-axis guide rails 16 that is substantially parallel to the X-axis direction. To the X-axis guide rails 16, an X-axis moving plate 18 is attached in a way that it is slidable along the X-axis direction. On a side of a lower surface of the X-axis moving plate 18, a nut portion (not illustrated) that constitutes a ball screw is disposed.

To this nut portion, a screw shaft 20, which is substantially parallel to the X-axis guide rails 16, is connected in a way that it is rotatable. To one end portion of the screw shaft 20, an X-axis pulse motor 22 is connected. By rotating the screw shaft 20 with the X-axis pulse motor 22, the X-axis moving plate 18 is moved along the X-axis guide rails 16 (X-axis direction).

On a side of an upper surface of the X-axis moving plate 18, a cylindrical table base 24 is arranged. On an upper part of the table base 24, a chuck table (holding unit) 26 is arranged for use to hold a workpiece 11. On a lower part of the table base 24, a rotary drive source (not illustrated) such as a motor is connected.

By a force generated by this rotary drive force of the horizontal moving mechanism 6, the chuck table 26 is rotated about an axis of rotation that is substantially parallel to a Z-axis direction. Further, the table base 24 and the chuck table 26 are moved along the X-axis direction (are fed for processing) with a force generated by the X-axis pulse motor 22 of the horizontal moving mechanism 6, and are moved along the Y-axis direction (are fed for indexing) with a force generated by the Y-axis pulse motor 14 of the horizontal moving mechanism 6.

The workpiece 11 is, for example, a disk-shaped wafer made of a semiconductor such as silicon. This workpiece 11 therefore has a circular front surface, and a circular back surface on a side opposite to the front surface. The workpiece 11 is defined on the side of the front surface thereof into a plurality of small regions by a plurality of streets (scribe lines) that have a predetermined width and intersect each other, and devices such as integrated circuits (ICs) are formed in the respective small regions. The laser processing machine 2 of the present embodiment is used, for example, when grooves are formed along the streets of this workpiece 11.

In the present embodiment, a circular tape 13 is bonded to the back surface (or the front surface) of the workpiece 11, and on an outer edge portion of the tape 13, an annular frame 15 surrounding the workpiece 11 is fixed. The workpiece 11 is therefore supported on the annular frame 15 via the tape 13. This enhances the handling ease of the workpiece 11. The workpiece 11 may however be processed in a state that the tape 13 is not bonded, or in a state that it is not supported on the annular frame 15.

It is to be noted that, in the present embodiment, the disk-shaped wafer made of a semiconductor such as silicon is used as the workpiece 11, but the material, shape, structure, size, and the like of the workpiece 11 are not limited by the details of the wafer exemplified in the present embodiment. For example, a substrate or the like made of another semiconductor material, ceramics, resin, or metal can also be used as the workpiece 11. Similarly, the type, number, shape, structure, size, arrangement, and the like of the devices are not limited by the details of the above-mentioned wafer. On the workpiece 11, no devices may be formed.

A part of an upper surface of the chuck table 26 is a holding surface 26a that comes into contact with the tape 13 (or the workpiece 11 if the tape 13 is not bonded to the workpiece 11) and holds the workpiece 11. Typically, this holding surface 26a is made of porous ceramics. The holding surface 26a is substantially parallel to the X-axis direction and Y-axis direction.

Further, the holding surface 26a is connected to a suction source (not illustrated) such as a vacuum pump via a channel (not illustrated) disposed inside the chuck table 26. Arranged around the chuck table 26 are four clamps 28 that can fix the annular frame 15 with the workpiece 11 supported thereon.

Disposed in a region on one side in the Y-axis direction of the horizontal moving mechanism 6 is a support structure 30 having a side surface that is substantially parallel to the Z-axis direction. On the side surface of this support structure 30, a vertical moving mechanism (height adjustment mechanism) 32 is arranged. The vertical moving mechanism 32 includes a pair of Z-axis guide rails 34, which is fixed on the side surface of the support structure 30 and is substantially parallel to the Z-axis direction. To the Z-axis guide rails 34, a Z-axis moving plate 36 is attached in a way that it is slidable along the Z-axis direction.

On a side of a rear surface (on a side of the Z-axis guide rails 34) of the Z-axis moving plate 36, a nut portion (not illustrated) that constitutes a ball screw is disposed. To this nut portion, a screw shaft (not illustrated), which is substantially parallel to the Z-axis guide rails 34, is connected in a way that it is rotatable. To one end portion of the screw shaft, a Z-axis pulse motor 38 is connected. By rotating the screw shaft with the Z-axis pulse motor 38, the Z-axis moving plate 36 is moved along the Z-axis guide rails 34 (Z-axis direction).

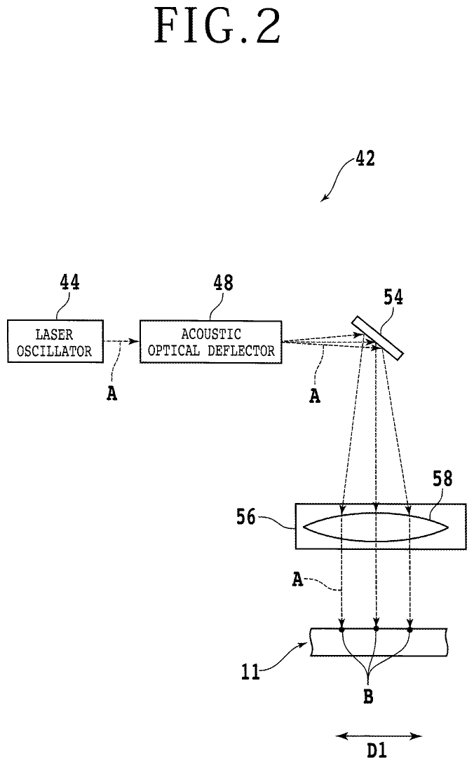

On a side of a front surface of the Z-axis moving plate 36, a support bracket 40 is fixed. On this support bracket 40, a laser beam irradiation unit 42 is supported at a portion thereof. The laser beam irradiation unit 42 can apply a laser beam A (see FIG. 2) so that the laser beam A is focused on the workpiece 11 held on the chuck table 26. FIG. 2 is a diagram illustrating the construction of the laser beam irradiation unit 42 in the laser processing machine 2 of FIG. 1. It is to be noted that some elements are also presented as function blocks in FIG. 2. As illustrated in FIG. 2, the laser beam irradiation unit 42 includes a laser oscillator 44 fixed, for example, on the base 4.

The laser oscillator 44 includes a laser medium typically such as neodymium-doped yttrium aluminum garnet (Nd:YAG) suited for laser oscillation, and generates the pulsed laser beam A of a wavelength having absorptivity for the workpiece 11. On a downstream side of the laser oscillator 44 as viewed in an advancing direction of the laser beam A, an acoustic optical deflector (AOD) (first focal-point moving unit) 48 is arranged, for example. The laser beam A radiated from the laser oscillator 44 enters this acoustic optical deflector 48.

The acoustic optical deflector 48 generates an acoustic wave (ultrasonic wave) corresponding to the power value and frequency of radio frequency power (RF power) supplied, and promptly adjusts the power and the advancing direction of the laser beam A using an interaction with the acoustic wave. Specifically, the power of the laser beam A is adjusted on the basis of the power value, and the advancing direction of the laser beam A is adjusted on the basis of the frequency. However, the power of the laser beam A may be adjusted inside the laser oscillator 44, or may be adjusted through a level controller such as an attenuator.

The laser beam A, the power and the advancing direction of which have been adjusted by the acoustic optical deflector 48, enters a cylindrical housing 50 (see FIG. 1) supported, for example, on the support bracket 40. On an end portion on a side of the horizontal moving mechanism 6 (on the other side in the Y-axis direction) of the housing 50, an irradiation head 52 (see FIG. 1) is disposed. In an upper part of the irradiation head 52, a mirror 54 is arranged, for example, and by this mirror 54, the advancing direction of the laser beam A is changed downward.

In a lower part of the irradiation head 52, a condenser 56 is arranged, for example. This condenser 56 focuses the laser beam A at a focal point B located below the irradiation head 52. The laser beam A is applied through the condenser 56 to the workpiece 11 held on the chuck table 26. It is to be noted that the condenser 56 includes an fθ lens 58, and focuses the laser beam A at the focal point B at a predetermined height from the holding surface 26a of the chuck table 26 irrespective of its advancing direction.

By the above-mentioned acoustic optical deflector 48, the focal point B of the laser beam A is moved, for example, in a first moving direction D1, which intersects the X-axis direction, on the workpiece 11. The first moving direction D1 is typically parallel to the Y-axis direction (perpendicular to the X-axis direction), but may be inclined with respect to the Y-axis direction. Further, the focal point B may exist inside the workpiece 11, or may exist outside (above) the workpiece 11. On an upper surface (the front surface) of the workpiece 11, the laser beam A has a diameter of, for example, approximately 3 μm to 1,000 μm.

As illustrated in FIG. 1, a camera (imaging unit) 60 is arranged in a region on one side in the X-axis direction of the irradiation head 52, and is fixed on the housing 50. The camera 60 includes, for example, a two-dimensional optical sensor such as a complementary metal-oxide semiconductor (CMOS) image sensor or a charge coupled device (CCD) image sensor sensitive to visible light, and is used when imaging the workpiece 11 held on the chuck table 26 etc.

With a force generated by the Z-axis pulse motor 38 of the vertical moving mechanism 32, the housing 50 and the irradiation head 52 of the laser beam irradiation unit 42 are moved together with the above-mentioned camera 60 along the Z-axis direction. In other words, the vertical moving mechanism 32 moves elements such as the mirror 54 and the condenser 56, which are disposed in the irradiation head 52, in a direction substantially perpendicular to the holding surface 26a of the chuck table 26.

It is to be noted that the present embodiment has been described taking, as an example, the case in which the laser oscillator 44 and the like are fixed on the base 4. However, the laser oscillator 44 and the like may be configured such that they are supported together with the housing 50 and the like by the vertical moving mechanism 32 and are movable along the Z-axis direction. As a further alternative, the irradiation head 52 may be provided with an actuator or the like so that, inside the irradiation head 52, the condenser 56 alone can be independently moved along the Z-axis direction.

To elements such as the horizontal moving mechanism 6, the vertical moving mechanism 32, the laser beam irradiation unit 42, and the camera 60, a controller (control unit) 62 is connected. The controller 62 is configured by a computer that includes, for example, a processing device 64 and a storage device 66, and is configured to control operation and the like of the above-mentioned individual elements so that the workpiece 11 is appropriately processed.

The processing device 64 is typically a central processing unit (CPU), and performs a variety of processing needed to control the above-mentioned elements. The storage device 66 includes, for example, a main storage device such as a dynamic random access memory (DRAM), and an auxiliary storage device such as a hard disk drive or a flash memory. Functions of this controller 62 are realized, for example, by operation of the processing device 64 according to software such as a program stored in the storage device 66.

An upper part of the base 4 is surrounded by a cover (not illustrated) that can accommodate the individual elements. On a side surface of the cover, a touch screen (input device, output device) 68 is arranged as a user interface. The controller 62 is also connected to the touch screen 68. For example, a variety of conditions to be applied upon processing of the workpiece 11 is inputted by an operator to the controller 62 via the touch screen 68.

It is to be noted that a keyboard, a mouse, or the like may be adopted as the input device. It is also to be noted that as the output device, a display device having no inputting function such as a liquid display, a speaker capable of transmitting information by speech or sound signals, an indicator lamp capable of transmitting information depending on the color of light or the state of light emission (emission, blinking, turn-off or the like of light), or the like may be adopted.

With the laser processing machine 2 configured as described above, the laser beam A is applied to the workpiece 11 in a predetermined mode specified by the program. A program that allows the processing device 64 to perform a series of processing required for the irradiation of the laser beam A is stored in a part of the storage device 66 that is, for example, a non-transitory storage medium readable by a computer or the like. According to this program, the controller 62 (processing device 64) performs procedures that are needed for the irradiation of the laser beam A to the workpiece 11.

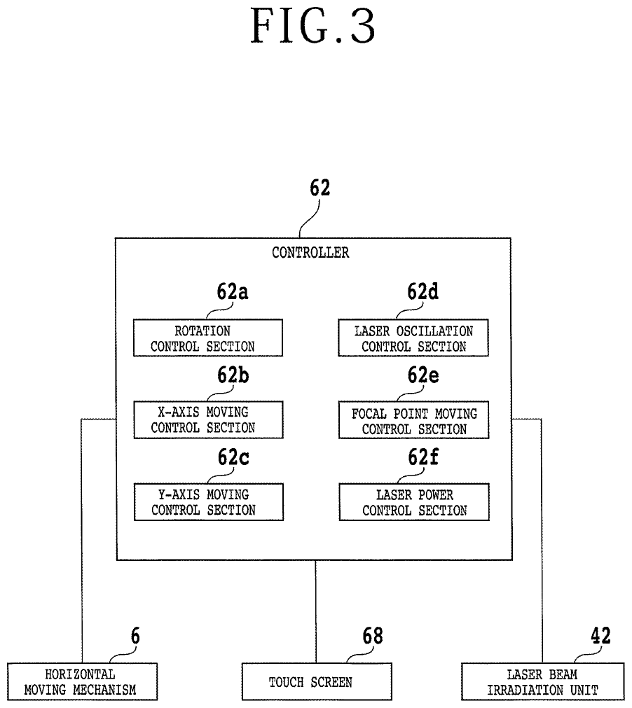

FIG. 3 is a function block diagram schematically illustrating the functional configuration of the controller 62 realized by a program according to the embodiment. It is to be noted that for the sake of convenience of illustration, FIG. 3 also illustrates, in combination, the horizontal moving mechanism 6 (including the rotary drive source that rotates the chuck table 26), the laser beam irradiation unit 42, the touch screen 68, and the like, all of which are connected to the controller 62.

As illustrated in FIG. 3, the controller 62 includes a rotation control section 62a that controls rotation of the chuck table 26 about the axis of rotation which is substantially parallel to the Z-axis direction. Upon receipt of a command, for example, to the effect that the workpiece 11 held on the chuck table 26 is to be processed along a desired street, this rotation control section 62a rotates the chuck table 26 by the rotary drive source of the horizontal moving mechanism 6 so that the direction of the width of the target street is perpendicular to the X-axis direction.

In other words, the rotary drive source rotates the chuck table 26 so that the direction of a length of the target street, the direction being perpendicular to the direction of the width of the target street, is parallel to the X-axis direction. It is to be noted that the command to the effect that the workpiece 11 is to be processed along the desired street is inputted by the operator to the controller 62 typically via the touch screen 68. However, this command may be generated on the basis of a program or the like inside the controller 62.

The controller 62 also includes an X-axis moving control section (processing feed control section) 62b that controls movement (processing feed) of the chuck table 26 along the X-axis direction, and a Y-axis moving control section (indexing feed control section) 62c that controls movement (indexing feed) of the chuck table 26 along the Y-axis direction.

Upon receipt of a command, for example, to the effect that the workpiece 11 held on the chuck table 26 is to be processed along a desired street, the X-axis moving control section 62b and the Y-axis moving control section 62c adjust the position of the chuck table 26 along the X-axis direction and the position of the chuck table 26 along the Y-axis direction by the horizontal moving mechanism (processing feed mechanism, indexing feed mechanism) 6.

Specifically, the horizontal moving mechanism (specifically, the processing feed mechanism) 6 adjusts the position of the chuck table 26 along the X-axis direction and the horizontal moving mechanism (specifically, the indexing feed mechanism) 6 adjusts the position of the chuck table 26 along the Y-axis direction, so that the irradiation head 52 is arranged above an extension of the target street along the direction of the length of the target street. Here, the procedures of the adjustments of the position along the X-axis direction and the position along the Y-axis direction may be performed before the procedure of the above-mentioned rotation, at the same time (in parallel with) the procedure of the rotation, or after the procedure of the rotation.

After completion of the procedure of the above-mentioned rotation and the procedures of the adjustments of the position along the X-axis direction and the position along the Y-axis direction, the X-axis moving control section 62b moves the chuck table 26 along the X-axis direction by the horizontal moving mechanism (processing feed mechanism) 6. In other words, the horizontal moving mechanism (processing feed mechanism) 6 relatively moves the chuck table 26 and the irradiation head 52 along the X-axis direction, whereby the workpiece 11 is allowed to pass through a region right below the irradiation head 52.

As a result, the focal point B of the laser beam A, which is located right below the irradiation head 52, moves relative to the chuck table 26 along the X-axis direction, and passes through the target street of the workpiece 11 along the direction of its length. As described above, the X-axis moving control section 62b relatively moves the focal point B of the laser beam A and the chuck table 26 along the X-axis direction with the direction of the width of the target street set perpendicular to the X-axis direction.

The controller 62 further includes a laser oscillation control section 62d that controls the generation of the laser beam A by the laser oscillator 44. With the focal point B of the laser beam A and the chuck table 26 relatively moving along the X-axis direction, for example, the laser oscillation control section 62d generates the laser beam A by the laser oscillator 44, and applies the laser beam A from the irradiation head 52 to the workpiece 11. As a result, the laser beam A is applied to the target street of the workpiece 11.

The controller 62 still further includes a focal point moving control section 62e that moves the focal point B of the laser beam A, and a laser power control section 62f that controls the power of the laser beam A. In the above-mentioned procedure of relatively moving the focal point B and the chuck table 26 along the X-axis direction, for example, the focal point moving control section 62e moves the focal point B in the first moving direction D1, which intersects the X-axis direction, in the range of the width of the target street by the acoustic optical deflector 48.

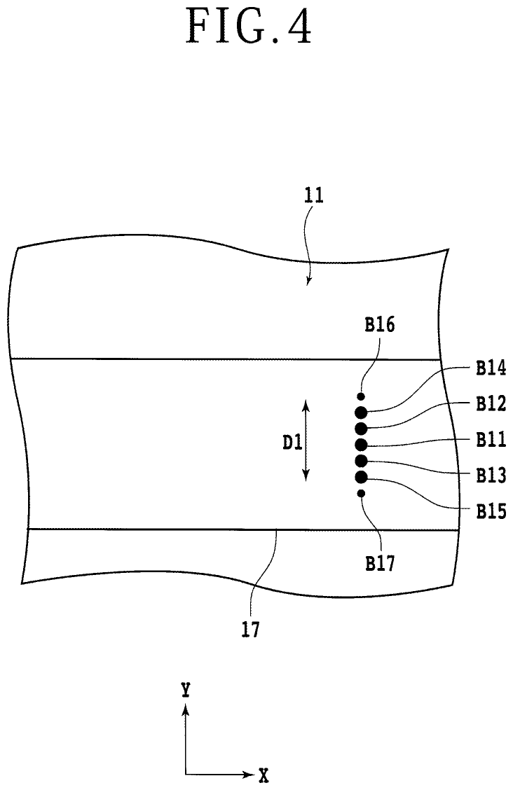

FIG. 4 is a fragmentary top view of the front surface of the workpiece 11, which illustrates how the focal point B is moved in the range of the width of a street (scribe line) 17 of the workpiece 11. In the present embodiment, the focal point moving control section 62e moves the focal point B in the first moving direction D1 so that the focal point B heads from the region on the center side toward the regions on the outer edge sides in the direction of the width of the street 17.

Specifically, the focal point moving control section 62e moves the focal point B, for example, from a position B11 on the center side illustrated in FIG. 4 toward the outer edge sides, in the order of a position B12, a position B13, a position B14, a position B15, a position B16, and a position B17, in accordance with a preset timing. The focal point B moved to the position B17 returns to the position B11 at the timing of the next movement. It is to be noted that the focal point moving control section 62e may move the focal point B in accordance with the timing at which the pulsed laser beam A is generated.

The intervals between the adjacent positions of the focal point B can be set as desired according to a repetition frequency upon oscillation of the laser beam A, the width of the street 17, required processing quality, and the like in a manner so that desired overlapping of regions applied by the laser beam A is realized. These intervals are, for example, 0.01 μm to 500 μm, with 2 μm being typical. Similarly, the number of the positions of the focal point B can also be set as desired.

As mentioned above, the focal point B and the chuck table 26 are relatively moved along the X-axis direction by the horizontal moving mechanism 6. The focal point B and the workpiece 11 therefore slightly move relative to each other while the focal point B moves from the position B11 to the position B17 along the first moving direction D1.

It is to be noted that, in FIG. 4, the focal point B and the chuck table 26 are relatively moved along the X-axis direction by the horizontal moving mechanism 6 so that the focal point B moves relative to the workpiece 11 in a direction opposite to the X-axis direction (in other words, in a leftward direction in FIG. 4). The speed and timing of the movement of the focal point B in the first moving direction D1 and the speed of the relative movement of the focal point B and the chuck table 26 along the X-axis direction are set in ranges where the street 17 of the workpiece 11 can be appropriately processed by the laser beam A.

The laser power control section 62f adjusts the power of the laser beam A by the acoustic optical deflector 48 so that, upon movement of the focal point B in the first moving direction D1 by the focal point moving control section 62e, the power of the laser beam A is smaller when the focal point B is located in the regions on the outer edge sides of the street 17 than when the focal point B is located in the region on the center side of the street 17.

Specifically, in the present embodiment, the acoustic optical deflector 48 adjusts the power of the laser beam A so that the power of the laser beam A is smaller when the focal point B is located at the position B16 and position B17 than when the focal point B is located at the position B11, position B12, position B13, position B14, and position B15. The power of the laser beam A when the focal point B is located at the position B16 and position B17 is adjusted to, for example, approximately 1% to 80% of the power of the laser beam A when the focal point B is located at the position B11, position B12, position B13, position B14, and position B15.

As a consequence, the laser beam A is applied with low power to the edges of a groove formed along the street 17 by the laser beam A of high power, so that contaminants such as debris and recast layers stuck on the edges of the groove are removed by the laser beam A of lower power. It is to be noted that, in FIG. 4, the position B11, position B12, position B13, position B14, position B15, position B16, and position B17 of the focal point B are indicated by dots, respectively, which have sizes (diameters) corresponding to the power levels of the laser beam A.

However, no particular limitations are imposed on the mode of movement of the focal point B and the mode of adjustment of the power of the laser beam A. For example, the focal point moving control section 62e may move the focal point B so that the focal point B heads from the position B16 on one of the outer edge sides (or the position B17 on the other one edge side) toward the position B17 on the other one edge side (or the position B16 on the one edge side) by way of the position B11 on the center side. Further, the laser power control section 62f may adjust the power of the laser beam A by the acoustic optical deflector 48 so that the power of the laser beam A sequentially decreases from the position B11 on the center side toward the position B16 and position 17 on the outer edge sides.

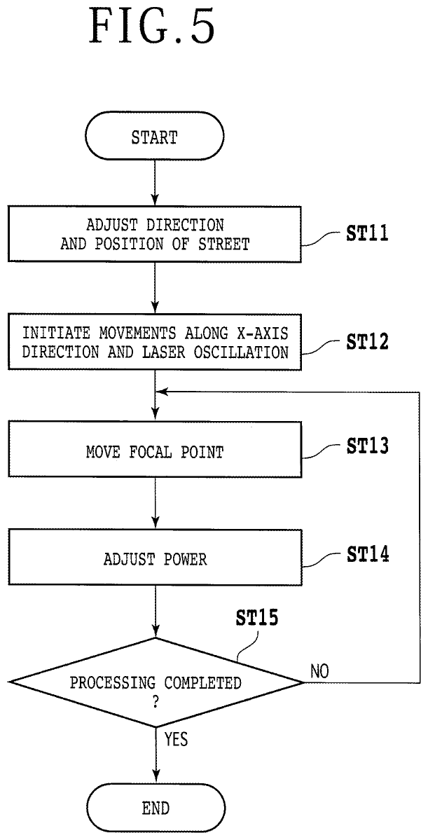

FIG. 5 is a flow chart illustrating a flow of processing when the laser processing machine 2 applies the laser beam A to the workpiece 11, that is, a processing method for the workpiece 11 according to the embodiment. When the controller 62 receives a command to the effect that the workpiece 11 is to be processed along the desired street 17, the rotation control section 62a, the X-axis moving control section 62b, and the Y-axis moving control section 62c first perform a procedure of adjusting the direction and position of the target street 17 relative to the irradiation head 52 (Step ST11).

Specifically, the rotation control section 62a rotates the chuck table 26 by the rotary drive source of the horizontal moving mechanism 6 so that the direction of the length of the target street 17 is parallel to the X-axis direction (in other words, the direction of the width is perpendicular to the X-axis direction). Further, the X-axis moving control section 62b and the Y-axis moving control section 62c adjust the positions of the chuck table 26 along the X-axis direction and Y-axis direction by the horizontal moving mechanism (specifically, the processing feed mechanism, and the indexing feed mechanism) 6 so that the irradiation head 52 is arranged above the extension of the target street 17 along the direction of the length of the target street 17.

After the direction and position of the target street 17 have been adjusted relative to the irradiation head 52, the laser oscillation control section 62d and the X-axis moving control section 62b perform, with the direction of the length of the target street 17 set parallel to the X-axis direction, a procedure of initiating laser oscillation and relatively moving the focal point B and the chuck table 26 along the X-axis direction (Step ST12).

Specifically, the laser oscillation control section 62d initiates the generation of the pulsed laser beam A by the laser oscillator 44. Further, the X-axis moving control section 62b moves the chuck table 26 along the X-axis direction by the horizontal moving mechanism (processing feed mechanism) 6 so that the focal point B of the laser beam A, which is located right below the irradiation head 52, passes through the street 17 of the workpiece 11 along the direction of its length.

After the initiation of the laser oscillation, the focal point moving control section 62e performs, with the focal point B and the chuck table 26 relatively moving along the X-axis direction, a procedure of moving the focal point B in the first moving direction D1, which intersects the X-axis direction, in the range of the width of the street by the acoustic optical deflector 48 (Step ST13). Specifically, the focal point moving control section 62e changes the position of the focal point B by the acoustic optical deflector 48 in the preset order.

Further, concurrently with the movement of the focal point B in the first moving direction D1, the laser power control section 62f performs a procedure of adjusting the power of the laser beam A by the acoustic optical deflector 48 so that the power of the laser beam A is smaller when the focal point B is located in the regions on the outer edge sides of the street 17 than when the focal point B is located in the region on the center side of the street 17 (Step ST14). Specifically, the laser power control section 62f adjusts the power of the laser beam A by the acoustic optical deflector 48 so that the power levels preset according to the positions of the focal point B are realized.

It is to be noted that the procedure of moving the focal point B in the first moving direction D1 and the procedure of adjusting the power of the laser beam A are repeated, for example, until a groove is formed along the entirety of the target street 17 and the processing of the workpiece 11 along the target street 17 is completed (“NO” in Step ST15). Obviously, after the groove has been formed along the entirety of the target street 17, grooves may be subsequently formed along the remaining streets 17 in similar procedures. When the processing of the workpiece 11 is completed along all the streets 17 (“YES” in Step ST15), the processing method according to the present embodiment for the workpiece 11 is completed.

As described above, when the focal point B of the laser beam A and the chuck table (holding unit) 26 relatively move along the X-axis direction (processing feed direction), the laser processing machine 2, the program, and the processing method according to the embodiment move the focal point B in the first moving direction D1, which intersects the X-axis direction, in the range of the width of the street (scribe line) 17, and controls the power of the laser beam A so that the power of the laser beam A is smaller when the focal point B is located in the regions on the outer edge sides of the street 17 than when the focal point B is located in the region on the center side of the street 17. Therefore, the groove is formed with the laser beam of high power applied to the region on the center side of the street 17, and in parallel with the formation of this groove, contaminants stuck in the groove are removed with the laser beam of low power applied to the regions on the outer edge sides of the street 17.

Further, according to the laser processing machine 2, the program, and the processing method according to the embodiment, the formation of the groove and the removal of the contaminants are performed in parallel by moving the focal point B with the acoustic optical deflector (first focal-point moving unit) 48 in the first moving direction D1, which intersects the X-axis direction, without splitting of the laser beam A through a diffraction grating or the like. Compared with the case in which the laser beam A is split through the diffraction grating, the position of the laser beam A to be applied to the workpiece 11 can therefore be flexibly changed because the position of the laser beam A to be applied to the workpiece 11 is moved in the first moving direction D1 by the acoustic optical deflector 48.

According to the embodiment, there are provided, as described above, the laser processing machine 2, the program, and the processing method, which can remove contaminants that stick in the groove while forming the groove in the workpiece 11 and can flexibly change the position of the laser beam A to be applied to the workpiece 11.

It is to be noted that the present invention can be practiced with various changes or modifications without being limited to the details of the above-mentioned embodiment. For example, the program that realizes the various procedures to be performed by the laser processing machine 2 is stored in the storage device 66 inside the controller 62 in the above-mentioned embodiment. However, this program may be recorded on a desired non-transitory storage medium readable by a computer or the like. For example, this program may be recorded on an optical disk such as a compact disk (CD) that can be distributed at low cost.

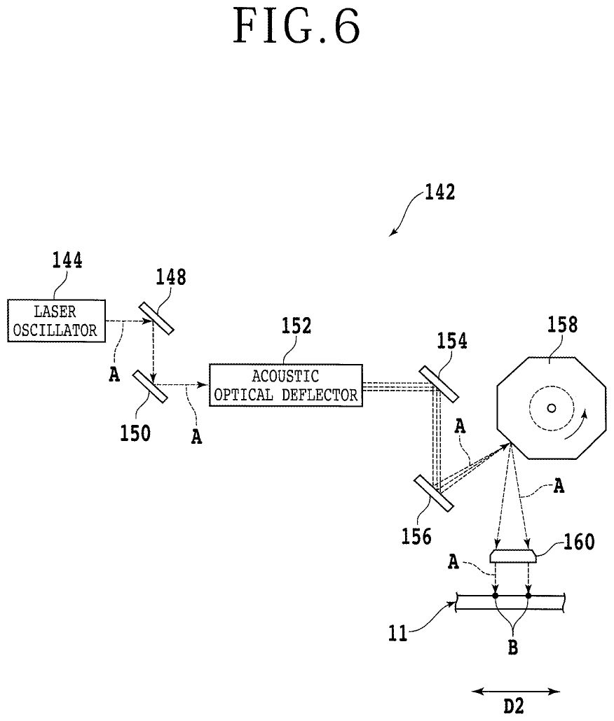

In the above-mentioned embodiment, the laser beam irradiation unit 42 is described, which can move the focal point B of the laser beam A in the first moving direction D1. A laser beam irradiation unit of a different configuration may however be incorporated in the laser processing machine 2. FIG. 6 is a diagram illustrating the construction of a laser beam irradiation unit 142 according to a modification. It is to be noted that some elements are presented as function blocks in FIG. 6.

Similarly to the laser beam irradiation unit 42 in the above-mentioned embodiment, the laser beam irradiation unit 142 according to the modification includes a laser oscillator 144. The laser oscillator 144 includes a laser medium typically such as Nd:YAG suited for laser oscillation, and generates a pulsed laser beam A of a wavelength having absorptivity for a workpiece 11.

On a downstream side of the laser oscillator 144 as viewed in an advancing direction of the laser beam A, a mirror 148, a mirror 150, and an acoustic optical deflector (AOD) (first focal-point moving unit) 152 are arranged. The laser beam A radiated from the laser oscillator 144 enters the acoustic optical deflector 152 via the mirror 148 and the mirror 150.

The acoustic optical deflector 152 generates an acoustic wave (ultrasonic wave) corresponding to the power value and frequency of radio frequency power (RF power) supplied, and promptly adjusts the power and the advancing direction of the laser beam A using an interaction with the acoustic wave. Specifically, the power of the laser beam A is adjusted on the basis of the power value, and the advancing direction of the laser beam A is adjusted on the basis of the frequency. However, the power of the laser beam A may be adjusted inside the laser oscillator 144, or may be adjusted through a level controller such as an attenuator.

The laser beam A, the power and the advancing direction of which have been adjusted by the acoustic optical deflector 152, is incident to a polygonal mirror (second focal-point moving unit) 158, which has a plurality of reflective facets, via a mirror 154 and a mirror 156. The polygonal mirror 158 is connected to a rotary drive source (not illustrated) such as a motor, and as a result of rotation of the polygonal mirror 158, the advancing direction of the laser beam A reflected by the reflective facets of the polygonal mirror 158 is changed. It is to be noted that the rotational speed of the polygonal mirror 158 is, for example, approximately 5,000 rpm to 30,000 rpm.

The laser beam A reflected by the polygonal mirror 158 is applied to the workpiece 11 through a condenser 160. The condenser 160 includes an fθ lens, and focuses the laser beam A at a focal point B at a predetermined height from the holding surface 26a of the chuck table 26 irrespective of its advancing direction. As described above, the laser beam irradiation unit 142 according to the modification includes the polygonal mirror 158 arranged between the laser oscillator 144 and the condenser 160.

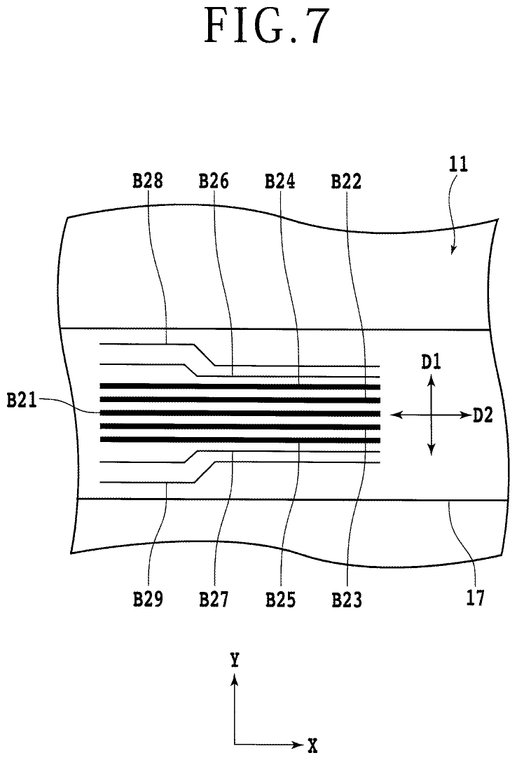

In this laser beam irradiation unit 142, the focal point B of the laser beam A is moved in a first moving direction D1 (see FIG. 7), which intersects the X-axis direction, on the workpiece 11 by the acoustic optical deflector 152, and is moved in a second moving direction D2 (see FIG. 7), which intersects the first moving direction D1, on the workpiece 11 by the polygonal mirror 158.

The first moving direction D1 is typically parallel to the Y-axis direction (perpendicular to the X-axis direction), but may be inclined with respect to the Y-axis direction. On the other hand, the second moving direction D2 is typically parallel to the X-axis direction (perpendicular to the Y-axis direction), but may be inclined with respect to the X-axis direction. Further, the focal point B may also exist inside the workpiece 11, or may also exist outside (above) the workpiece 11. On an upper surface (front surface) of the workpiece 11, the laser beam A has a diameter of, for example, approximately 3 μm to 1,000 μm.

Some elements of the laser beam irradiation unit 142, such as the laser oscillator 144, are fixed on the base 4 of the laser processing machine 2, and some other elements such as the condenser 160 are accommodated in the housing 50, the irradiation head 52 or the like supported on the vertical moving mechanism 32. However, the laser oscillator 144 and the like may be configured such that they are supported together with the housing 50 and the like by the vertical moving mechanism 32 and are movable along the Z-axis direction. Further, the irradiation head 52 may be provided with an actuator or the like to move the condenser 160 and the like in the Z-axis direction.

Functions of the controller 62, which are realized by a program, are similar to those in the above-mentioned embodiment. If the laser beam irradiation unit 142 of the modification is used, however, the focal point moving control section 62e moves the focal point B in the first moving direction D1, which intersects the X-axis direction, in the range of the width of the street 17, and also moves the focal point B in the second moving direction D2 that intersects the first moving direction D1.

Specifically, in the procedure of relatively moving the focal point B and the chuck table 26 along the X-axis direction, the focal point moving control section 62e moves the focal point B in the first moving direction D1, which intersects the X-axis direction, in the range of the width of the street 17 by the acoustic optical deflector 152. In the procedure of relatively moving the focal point B and the chuck table 26 along the X-axis direction, the focal point moving control section 62e also moves the focal point B in the second moving direction D2, which intersects the first moving direction D1, by the polygonal mirror 158.

FIG. 7 is a fragmentary top view of the front surface of the workpiece 11, which illustrates how the focal point B is moved in the range of the width of the street 17 according to the modification. In this modification, the focal point moving control section 62e moves the focal point B in the first moving direction D1 so that the focal point B heads from the region on the center side toward the regions on the outer edge sides in the direction of the width of the street 17, and also moves the focal point B in the second moving direction D2 in a predetermined range.

Specifically, the focal point moving control section 62e moves the focal point B, for example, from a position B21 on the center side illustrated in FIG. 7 toward the outer edge sides, in the order of a position B22, a position B23, a position B24, a position B25, a position B26, a position B27, a position B28, and a position B29, all illustrated in FIG. 7, in accordance with a preset timing. The focal point B moved to the position B29 returns to the position B21 at the timing of the next movement. It is to be noted that the focal point moving control section 62e may move the focal point B in accordance with the timing at which the pulsed laser beam A is generated.

The intervals between the adjacent positions of the focal point B can be set as desired according to a repetition frequency upon oscillation of the laser beam A, the width of the street 17, required processing quality, and the like in a manner so that desired overlapping of regions applied by the laser beam A is realized. These intervals are, for example, 0.01 μm to 500 μm, with 10 μm being typical. Similarly, the number of the positions of the focal point B can also be set as desired.

The focal point moving control section 62e also moves the focal point B in the second moving direction D2 in the predetermined range, for example, so that the focal point B heads from a forward side toward a backward side in the direction in which the focal point B and the chuck table 26 (in other words, the workpiece 11) relatively move. The range of the movement in the second moving direction D2 can be set as desired according to the performance of the polygonal mirror 158, required processing quality, and the like, and is, for example, 0.1 to 299 mm, with 20 mm being typical.

As described above, in the modification, the focal point moving control section 62e moves the focal point B in the first moving direction D1 by the acoustic optical deflector 152 and also moves the focal point B in the second moving direction D2 by the polygonal mirror 158, while the X-axis moving control section 62b relatively moves the focal point B and the chuck table 26 in the X-axis direction by the horizontal moving mechanism (processing feed mechanism) 6.

It is to be noted that, in this modification, the focal point B and the chuck table 26 are relatively moved along the X-axis direction so that the focal point B moves relative to the workpiece 11 in a direction opposite to the X-axis direction (in other words, in a leftward direction in FIG. 7). The processing of the workpiece 11 therefore proceeds from the forward side (a right side in FIG. 7) toward the backward side (a left side in FIG. 7) in the direction in which the focal point B and the chuck table 26 relatively move.

The speed and timing of the movement of the focal point B in the first moving direction D1, the speed and timing of the movement of the focal point B in the second moving direction D2, and the speed of the relative movement of the focal point B and the chuck table 26 along the X-axis direction are set in ranges where the street 17 of the workpiece 11 can be appropriately processed by the laser beam A. It is to be noted that, in the movement of the focal point B in the first moving direction D1 which is realized by the acoustic optical deflector 152 in this modification, the speed of the movement is fast and the range of the movement is narrow, compared with the movement of the focal point B in the second moving direction D2 which is realized by the polygonal mirror 158.

In this modification, the laser power control section 62f also adjusts the power of the laser beam A by the acoustic optical deflector 152 so that, upon movements of the focal point B in the first moving direction D1 and second moving direction D2 by the focal point moving control section 62e, the power of the laser beam A is smaller when the focal point B is located in the regions on the outer edge sides of the street 17 than when the focal point B is located in the region on the center side of the street 17.

Specifically, the acoustic optical deflector 152 adjusts the power of the laser beam A so that the power of the laser beam A is smaller when the focal point B is located at the position B26, position B27, position B28, and position B29 than when the focal point B is located at the position B21, position B22, position B23, position B24, and position B25. The power of the laser beam A when the focal point B is located at the position B26, position B27, position B28, and position B29 is adjusted to, for example, approximately 1% to 80% of the power of the laser beam A when the focal point B is located at the position B21, position B22, position B23, position B24, and position B25.

As a consequence, the laser beam A is applied with low power to the edges of a groove formed along the street 17 by the laser beam A of high power, so that contaminants such as debris and recast layers stuck on the edges of the groove are removed by the laser beam A of low power. It is to be noted that, in FIG. 7, the position B21, position B22, position B23, position B24, position B25, position B26, position B27, position B28, and position B29 of the focal point B are indicated by lines, respectively, which have thicknesses (widths) corresponding to the power levels of the laser beam A.

In addition, in this modification, the range of the movement of the focal point B in the first moving direction D1 is changed as illustrated in FIG. 7 when the focal point B moves in the second moving direction D2. The focal point moving control section 62e controls the range of the movement of the focal point B in the first moving direction D1, for example, so that the range of the movement of the focal point B in the first moving direction D1 is wider on the backward side than on the forward side in the direction in which the focal point B and the chuck table 26 (in other words, the workpiece 11) relatively move.

Described more specifically, the range of the movement of the focal point B in the first moving direction D1 is changed so that the position B26, position B27, position B28, and position B29 of the focal point B on the backward side (the left side in FIG. 7) are located outside the position B26, position B27, position B28, and position B29 of the focal point B on the forward side (the right side in FIG. 7) respectively. As a consequence, the laser beam A of small power is applied in a wider range in the direction of the width of the street 17, so that contaminants such as debris and recast layers stuck on the edges of the groove are more appropriately removed by the laser beam A of low power.

However, no particular limitations are imposed on the mode of movement of the focal point B and the mode of adjustment of the power of the laser beam A. For example, the focal point moving control section 62e may move the focal point B so that the focal point B heads from the position B28 on one of the outer edge sides (or the position B29 on the other one edge side) toward the position B29 on the other one edge side (or the position B28 on the one edge side) by way of the position B21 on the center side. Further, the laser power control section 62f may also adjust the power of the laser beam A by the acoustic optical deflector 152 so that the power of the laser beam A sequentially decreases from the position B21 on the center side toward the position B28 and position 29 on the outer edge sides.

Furthermore, the laser power control section 62f may also control the power of the laser beam A by the acoustic optical deflector 152 so that the power of the laser beam A is smaller at the position B26, position B27, position B28, and position B29 of the focal point B, which are located on the backward side (the left side in FIG. 7), than at the position B26, position B27, position B28, and position B29 of the focal point B, which are on the forward side (the right side in FIG. 7) and are located on relatively inner sides. In this case, contaminants such as debris and recast layers, which may stick the edges of the groove on the forward side where the power of the laser beam A is relatively high, are appropriately removed by the laser beam A of low power applied to wider ranges (outer sides) on the backward side.

In the embodiment and modification mentioned above, the movement of the focal point B in the first moving direction D1 is realized by the acoustic optical deflector 48 or 152. However, the movement of the focal point B in the first moving direction D1 may also be realized by a galvanometer scanner, a resonant scanner, a polygonal scanner (polygonal mirror), or the like. In the modification mentioned above, the movement of the focal point B in the second moving direction D2 is realized by the polygonal mirror 158. Similarly, this movement of the focal point B in the second moving direction D2 may also be realized by a galvanometer scanner, a resonant scanner, an acoustic optical deflector, or the like.

Moreover, the construction, the method, and the like according to the above-mentioned embodiment and modification can be practiced with appropriate changes or modifications within the scope not departing from the objects of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing machine for processing a workpiece by applying a laser beam along scribe lines having a predetermined width and set on the workpiece, comprising:
a holding unit that holds the workpiece;
a laser beam irradiation unit that applies the laser beam so that the laser beam is focused on the workpiece held on the holding unit;
a processing feed mechanism that relatively moves a focal point, at which the laser beam is focused, and the holding unit along a processing feed direction; and
a controller that has a processing device and a storage device and is configured to control the laser beam irradiation unit and the processing feed mechanism according to a program stored in the storage device, wherein
the laser beam irradiation unit has
a laser oscillator that generates the laser beam,
a condenser that focuses the laser beam, which has been generated by the laser oscillator, on the focal point, and
a first focal-point moving unit that is arranged between the laser oscillator and the condenser and moves the focal point in a first moving direction, which intersects the processing feed direction, on the workpiece, and
the controller performs, to form a groove along the scribe line, according to the program
a procedure of relatively moving the focal point and the holding unit along the processing feed direction with a direction of the width of the scribe line set perpendicular to the processing feed direction,
a procedure of moving the focal point in the first moving direction in a range of the width of the scribe line when the focal point and the holding unit relatively move along the processing feed direction, and
a procedure of controlling power of the laser beam so that, upon movement of the focal point in the first moving direction, the power of the laser beam is smaller when the focal point is located in regions on outer edge sides of the scribe line than when the focal point is located in a region on a center side of the scribe line.

2. The laser processing machine according to claim 1, wherein
the laser beam irradiation unit further has a second focal-point moving unit that is arranged between the laser oscillator and the condenser and moves the focal point in a second moving direction, which intersects the first moving direction, on the workpiece, and
the controller further performs, according to the program, a procedure of moving the focal point in the second moving direction when the focal point and the holding unit relatively move along the processing feed direction.

3. The laser processing machine according to claim 2, wherein,
upon movement of the focal point in the second moving direction, the controller further performs, according to the program, a procedure of controlling a range of the movement of the focal point in the first moving direction so that the range of the movement of the focal point in the first moving direction is wider on a backward side than on a forward side in the direction in which the focal point and the holding unit relatively move.

4. A non-transitory recording medium recording a program for use when forming a groove along a scribe line, which has a predetermined width and is set on a workpiece, by a laser processing machine having
a holding unit that holds the workpiece,
a laser beam irradiation unit that applies a laser beam so that the laser beam is focused on the workpiece held on the holding unit,
a processing feed mechanism that relatively moves a focal point, at which the laser beam is focused, and the holding unit along a processing feed direction, and
a controller that has a processing device and a storage device and is configured to control the laser beam irradiation unit and the processing feed mechanism according to the program,
the laser beam irradiation unit having
a laser oscillator that generates the laser beam,
a condenser that focuses the laser beam, which has been generated by the laser oscillator, on the focal point, and
a first focal-point moving unit that is arranged between the laser oscillator and the condenser and moves the focal point in a first moving direction, which intersects the processing feed direction, on the workpiece,
the program causing the controller to perform:
a procedure of relatively moving the focal point and the holding unit along the processing feed direction with a direction of the width of the scribe line set perpendicular to the processing feed direction;
a procedure of moving the focal point in the first moving direction in a range of the width of the scribe line when the focal point and the holding unit relatively move along the processing feed direction; and
a procedure of controlling power of the laser beam so that, upon movement of the focal point in the first moving direction, the power of the laser beam is smaller when the focal point is located in regions on outer edge sides of the scribe line than when the focal point is located in a region on a center side of the scribe line.

5. The non-transitory recording medium according to claim 4, wherein
the laser beam irradiation unit further has a second focal-point moving unit that is arranged between the laser oscillator and the condenser and moves the focal point in a second moving direction, which intersects the first moving direction, on the workpiece, and
the program causes the controller to further perform a procedure of moving the focal point in the second moving direction when the focal point and the holding unit relatively move along the processing feed direction.

6. The non-transitory recording medium according to claim 5, wherein
the program causes, upon movement of the focal point in the second moving direction, the controller to further perform a procedure of controlling a range of the movement of the focal point in the first moving direction so that the range of the movement of the focal point in the first moving direction is wider on a backward side than on a forward side in the direction in which the focal point and the holding unit relatively move.

7. A processing method of a workpiece, the processing method being for use when forming a groove along a scribe line, which has a predetermined width and is set on the workpiece, by a laser processing machine having
a holding unit that holds the workpiece,
a laser beam irradiation unit that applies a laser beam so that the laser beam is focused on the workpiece held on the holding unit, and
a processing feed mechanism that relatively moves a focal point, at which the laser beam is focused, and the holding unit along a processing feed direction, the processing method comprising:
a step of relatively moving the focal point and the holding unit along the processing feed direction with a direction of the width of the scribe line set perpendicular to the processing feed direction;
a step of moving the focal point in a first moving direction, which intersects the processing feed direction, in a range of the width of the scribe line when the focal point and the holding unit relatively move along the processing feed direction; and
a step of controlling power of the laser beam so that, upon movement of the focal point in the first moving direction, the power of the laser beam is smaller when the focal point is located in regions on outer edge sides of the scribe line than when the focal point is located in a region on a center side of the scribe line.

8. The processing method according to claim 7, further comprising:
a step of moving the focal point in a second moving direction, which intersects the first moving direction, when the focal point and the holding unit relatively move along the processing feed direction.

9. The processing method according to claim 8, further comprising:
a step of, upon movement of the focal point in the second moving direction, controlling a range of the movement of the focal point in the first moving direction so that the range of the movement of the focal point in the first moving direction is wider on a backward side than on a forward side in the direction in which the focal point and the holding unit relatively move.
